(19) United States
(12) Patent Application Publication
(10) Pub. No.: US 2026/0239993 A1
(43) Pub. Date: Aug. 13, 2026

(54) SEMICONDUCTOR PACKAGE AND METHOD FOR FABRICATING THE SAME

(71) Applicant: Samsung Electronics Co., Ltd., Suwon-si (KR)

(72) Inventors: Minyoung Lee, Suwon-si (KR); Jongyoun Kim, Suwon-si (KR); Myeong Han Bae, Suwon-si (KR); Minjun Bae, Suwon-si (KR)

(73) Assignee: Samsung Electronics Co., Ltd., Suwon-si (KR)

(21) Appl. No.: 19/275,139

(22) Filed: Jul. 21, 2025

(30) Foreign Application Priority Data
Feb. 10, 2025 (KR) 10-2025-0016913

(51) Int. Cl. H01L 23/544; H01L 21/48; H01L 21/56; H01L 23/00; H01L 23/31; H01L 23/498; H01L 23/538; H01L 25/18; H10B 80/00; H10D 80/30

(52) U.S. Cl. CPC H10W 46/00; H10W 70/611; H10W 70/66; H10W 90/00; H10W 90/401; H10B 80/00; H10D 80/30; H10W 46/101; H10W 46/301; H10W 70/093; H10W 70/65; H10W 72/227; H10W 72/856; H10W 72/877; H10W 74/016; H10W 74/117; H10W 90/20; H10W 90/24; H10W 90/724; H10W 90/732; H10W 90/734; H10W 90/794

(57) ABSTRACT

A semiconductor package according to embodiments may comprising: a redistribution structure; a semiconductor die on the redistribution structure; a molding material covering the semiconductor die on the redistribution structure; a dielectric layer on the molding material, the dielectric layer including a first surface contacting the molding material and a second surface opposite the first surface; and a metal layer covering all of the second surface and including a marking pattern.

### CROSS-REFERENCE TO RELATED APPLICATIONS

This present application claims priority to and the benefit under 35 U.S.C. §119(a)-(d) of Korean Patent Application No. 10-2025-0016913, filed on Feb. 10, 2025, in the Korean Intellectual Property Office, the entire disclosure of which is incorporated herein by reference.

### BACKGROUND

The present disclosure relates to a semiconductor package and a method for manufacturing the same.

In order to identify a product, a marking pattern indicating information about the manufacturer, manufacturing date, product name, product type, and product specifications of the product may be formed on a surface exposed to the outside of the semiconductor package. The marking pattern is manufactured by disposing a redistribution structure on a molding material covering semiconductor dies within a semiconductor package, forming a dielectric layer for marking (e.g., an epoxy molding compound (EMC), an Ajinomoto build-up film (ABF), or a back side protection film) on the redistribution structure, and using a laser to form a predetermined pattern on the marking dielectric layer.

In this way, to form a marking pattern on a semiconductor package, it is necessary to form a separate marking dielectric layer on the redistribution structure, and several additional processes must be performed for this purpose. In addition, when performing an additional process to form a dielectric layer for marking and form a marking pattern on the dielectric layer for marking, the visibility of the marking pattern may deteriorate because a redistribution structure including a photo-imageable dielectric PID with relatively low light reflectivity as its main material is located under the dielectric layer for marking.

### SUMMARY

The problem to be solved by the present disclosure is to provide a semiconductor package having a marking pattern formed on a metal layer deposited to form a redistribution structure.

A semiconductor package according to embodiments may comprise: a redistribution structure; a semiconductor die on the redistribution structure; a molding material covering the semiconductor die on the redistribution structure; a dielectric layer on the molding material, the dielectric layer including a first surface contacting the molding material and a second surface opposite the first surface; and a metal layer covering all of the second surface and including a marking pattern.

A semiconductor package according to embodiments may comprise: a redistribution structure; a plurality of conductive posts on the redistribution structure; a semiconductor stack on the redistribution structure, the semiconductor stack comprising a plurality of semiconductor dies that are stacked, the semiconductor stack being disposed to be spaced apart in a vertical direction from the redistribution structure, and each of the plurality of conductive posts being connected to a corresponding semiconductor die among the plurality of semiconductor dies; a molding material covering the semiconductor stack and the plurality of conductive posts on the redistribution structure; a dielectric layer on the molding material, the dielectric layer comprising a first surface contacting the semiconductor stack and the molding material, and a second surface opposite the first surface; and a metal layer covering all of the second surface and comprising a marking pattern.

A semiconductor package according to embodiments may comprise: a first redistribution structure; a plurality of first conductive posts on the first redistribution structure; a plurality of second conductive posts on the first redistribution structure; a first semiconductor stack on the first redistribution structure, the first semiconductor stack comprising a plurality of first semiconductor dies that are stacked, the first semiconductor stack being disposed to be vertically spaced apart from the first redistribution structure, each of the plurality of first conductive posts being connected to a corresponding first semiconductor die of the plurality of first semiconductor dies; a first molding material covering the first semiconductor stack, the plurality of first conductive posts, and the plurality of second conductive posts on the first redistribution structure; a second redistribution structure on the first molding material, the second redistribution structure comprising a first dielectric layer and a plurality of vias in the first dielectric layer, each of the plurality of second conductive posts being connected to a corresponding via of the plurality of vias; a plurality of third conductive posts on the second redistribution structure; a second semiconductor stack on the second redistribution structure, the second semiconductor stack comprising a plurality of second semiconductor dies that are stacked, the second semiconductor stack being disposed to be vertically spaced apart from the second redistribution structure, each of the plurality of third conductive posts being connected to a corresponding second semiconductor die of the plurality of second semiconductor dies; a second molding material covering the second semiconductor stack and the plurality of third conductive posts on the second redistribution structure; a second dielectric layer on the second molding material, the second dielectric layer comprising a first surface contacting the second semiconductor stack and the second molding material, and a second surface opposite the first surface; and a metal layer covering all of the second surface and comprising a marking pattern.

A method for manufacturing a semiconductor package according to embodiments may comprise: forming a metal layer on a carrier; forming a dielectric layer on the metal layer, the dielectric layer including a first surface and a second surface opposite the first surface, and the metal layer covering all of the second surface; attaching a semiconductor die on the first surface of the dielectric layer; molding the semiconductor die on the first surface of the dielectric layer with a molding material; forming a redistribution structure on the molding material; and removing the carrier and forming a marking pattern on the metal layer.

A marking pattern may be formed on a metal layer that is essentially deposited to form a redistribution structure, and a separate marking dielectric layer may not be formed on the redistribution structure. This allows the process performed to form a dielectric layer for marking to be excluded from the manufacturing process of the semiconductor package.

Since a marking pattern may be formed on a metal layer having a relatively higher light reflectance than the light reflectance of the dielectric layer for marking, the visibility of the marking pattern may be improved.

### BRIEF DESCRIPTION OF THE DRAWINGS

FIG. 1 is a cross-sectional view illustrating a semiconductor package of embodiments.

FIGS. 2 to 6 are cross-sectional views illustrating a method for manufacturing the semiconductor package of FIG. 1.

FIG. 7 is a cross-sectional view illustrating a semiconductor package of embodiments.

FIGS. 8 to 10 are cross-sectional views illustrating a method for manufacturing the semiconductor package of FIG. 7.

FIG. 11 is a cross-sectional view illustrating a semiconductor package of embodiments.

FIGS. 12 to 16 are cross-sectional views illustrating a method for manufacturing the semiconductor package of FIG. 11.

FIG. 17 is a cross-sectional view illustrating a semiconductor package of embodiments.

FIGS. 18 to 20 are cross-sectional views illustrating a method for manufacturing the semiconductor package of FIG. 17.

### DETAILED DESCRIPTION

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown.

Throughout the specification, when a part is said to be “connected” to another part, this includes not only “directly connected” but also “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, throughout the specification, when referring to “a plane view”, it means that the target portion is viewed from above, and when referring to “a cross-section view”, it means that a cross section of the target portion cut vertically is viewed from a side.

Hereinafter, with reference to the drawings, a semiconductor package 100A, 100B, 200A, and 200B of embodiments and a method for manufacturing the semiconductor package 100A, 100B, 200A, and 200B will be described.

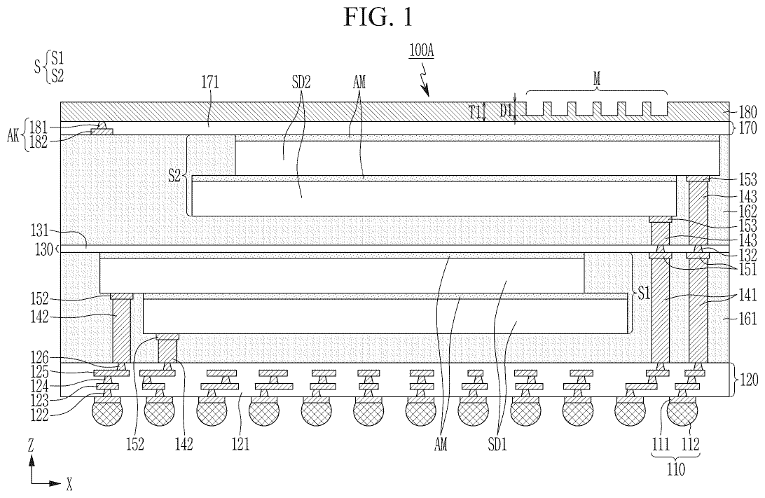

FIG. 1 is a cross-sectional view illustrating a semiconductor package (100A) of embodiments.

Referring to FIG. 1, a semiconductor package 100A may include an external connection structure 110, a first redistribution structure (front side redistribution structure; FRDL) 120, first conductive posts 141, second conductive posts 142, a first semiconductor stack S1, bonding pads 151, a first molding material 161, a second redistribution structure 130, third conductive posts 143, a second semiconductor stack S2, a third redistribution structure (back side redistribution structure; BRDL) 170, and a metal layer 180. In embodiments, the semiconductor package 100A may include a System In Package SIP. A semiconductor package 100A is a semiconductor package that implements two or more semiconductor dies into one semiconductor package and may operate as one chip. In embodiments, the semiconductor package 100A may be a semiconductor package manufactured based on a Fan Out Wafer Level Package FOWLP or a Fan Out Panel Level Package FOPLP technology. The first semiconductor stack S1 and the second semiconductor stack S2 may each be named a semiconductor stack S. In embodiments according to the present disclosure, a semiconductor package 100A including a first semiconductor stack S1 and a second semiconductor stack S2 is illustrated and described, but is not limited thereto, and a semiconductor package 100A including a larger number of semiconductor stacks S may be included in the present disclosure.

The external connection structure 110 may be disposed on the lower surface of the first redistribution structure 120. The external connection structure 110 may include conductive pads 111 and external connection members 112. Each of the conductive pads 111 may electrically connect a corresponding first redistribution via 122 among the first redistribution vias 122 of the first redistribution structure 120 to a corresponding external connection member 112 among the external connection members 112. External connection members 112 may electrically connect the semiconductor package 100A to an external device (not shown).

The first redistribution structure 120 may be disposed on the external connection structure 110. The first redistribution structure 120 may include a dielectric 121, and first redistribution vias 122, first redistribution lines 123, second redistribution vias 124, second redistribution lines 125, and third redistribution vias 126 within the dielectric 121. In other embodiments, a first redistribution structure 120 including fewer or more redistribution lines and redistribution vias may be included within the scope of the present disclosure.

The dielectric 121 may protect and insulate the first redistribution vias 122, the first redistribution lines 123, the second redistribution vias 124, the second redistribution lines 125, and the third redistribution vias 126. First conductive posts 141, second conductive posts 142, and first molding material 161 may be disposed on the upper surface of the dielectric 121. Conductive pads 111 may be disposed on the lower surface of the dielectric 121.

The first redistribution vias 122, the first redistribution lines 123, the second redistribution vias 124, the second redistribution lines 125, and the third redistribution vias 126 are disposed sequentially from below and may form signal, ground, and power routing paths. The first redistribution lines 123 and the second redistribution lines 125 may extend in a horizontal direction within the dielectric 121. The first redistribution vias 122, the second redistribution vias 124, and the third redistribution vias 126 may extend in a vertical direction within the dielectric (121). The first redistribution vias 122, the second redistribution vias 124, and the third redistribution vias 126 may each have a shape in which the width in the horizontal direction decreases from the bottom to the top.

The first conductive posts 141 may be disposed on the first redistribution structure (120). Each of the first conductive posts 141 may be connected to a corresponding first semiconductor die SD1 among the first semiconductor dies SD1 of the first semiconductor stack S1. Each of the first conductive posts 141 may be disposed between a corresponding third redistribution via 126 among the third redistribution vias 126 of the first redistribution structure 120 and a corresponding bonding pad 151 among the bonding pads 151. Each of the first conductive posts 141 may electrically connect a corresponding bonding pad 151 among the bonding pads 151 to a corresponding third redistribution via 126 among the third redistribution vias 126 of the first redistribution structure 120. The side of the first conductive posts 141 may be surrounded by the first molding material 161. Each of the first conductive posts 141 may form signal, ground, and power routing paths for a corresponding second semiconductor die SD2 among the second semiconductor dies SD2 of the second semiconductor stack S2.

The second conductive posts 142 may be disposed on the first redistribution structure 120. Each of the second conductive posts 142 may be disposed between a corresponding third redistribution via 126 of the third redistribution vias 126 of the first redistribution structure 120 and a corresponding first connection pad 152 of the first connection pads 152. Each of the second conductive posts 142 may electrically connect a corresponding first connection pad 152 among the first connection pads 152 to a corresponding third redistribution via 126 among the third redistribution vias 126 of the first redistribution structure 120. The side of the second conductive posts 142 may be surrounded by the first molding material 161. Each of the second conductive posts 142 may form signal, ground, and power routing paths for a corresponding first semiconductor die SD1 among the first semiconductor dies SD1 of the first semiconductor stack S1.

The first semiconductor stack S1 may be disposed on the first redistribution structure 120. The first semiconductor stack S1 may be arranged to be spaced apart from the first redistribution structure 120 in the vertical direction (Z direction). The first semiconductor stack S1 may include first semiconductor dies SD1 that are stacked in a vertical direction (Z direction) and adhesive members AM that are disposed alternately with the first semiconductor dies SD1. The number of first semiconductor dies SD1 included in the first semiconductor stack S1 may be determined by considering the function and performance of the semiconductor package 100A and the connection between the first redistribution structure 120 and the first semiconductor dies SD1. Although the drawings according to the present disclosure illustrate a first semiconductor stack S1 including two first semiconductor dies SD1, the present disclosure is not limited thereto, and a first semiconductor stack S1 including fewer or more first semiconductor dies SD1 may be included within the scope of the present disclosure. The first semiconductor dies SD1 may be stacked sequentially from below and with an offset in the first horizontal direction (X direction).

The first semiconductor die SD1 may include an active surface and a back side opposite the active surface. The first semiconductor die SD1 may be disposed so that its active surface faces the first redistribution structure 120. The first semiconductor die SD1 may include a device layer and a wiring layer on the active surface. The device layer may include an integrated circuit structure having integrated circuit regions. In embodiments, the integrated circuit structure may include at least one of an active device and a passive device. In embodiments, the integrated circuit structure may include a memory cell array, a transistor, a capacitor, an inductor, or a resistor. The wiring layer may be disposed on the device layer. The wiring layer may include signal wiring lines, power wiring lines, contact plugs, and intermetal dielectric IMD. In embodiments, the first semiconductor die SD1 may include a volatile or non-volatile memory die.

Each of the first semiconductor dies SD1 of the first semiconductor stack S1 may include first connection pads 152 arranged on an active surface. The first connection pads 152 may be disposed in a row and conformally along the side of the first semiconductor die SD1. Each of the first connection pads 152 may be disposed between a corresponding second conductive post 142 among the second conductive posts 142 and the wiring of the first semiconductor die SD1. Each of the first connection pads 152 may electrically connect a corresponding second conductive post 142 among the second conductive posts 142 to the wiring of the first semiconductor die SD1. In embodiments, the first connection pads 152 may include at least one of copper, nickel, zinc, gold, silver, platinum, palladium, chromium, titanium, and alloys thereof.

Bonding pads 151 may be disposed between the first conductive posts 141 and the second redistribution structure 130. Each of the bonding pads 151 may be disposed between a corresponding first conductive post 141 among the first conductive posts 141 and a corresponding via 132 among the vias 132. Each of the bonding pads 151 may electrically connect a corresponding via 132 among the vias 132 to a corresponding first conductive post 141 among the first conductive posts 141.

The first molding material 161 may cover the first conductive posts 141, the second conductive posts 142, the first semiconductor stack S1, and the bonding pads 151 on the first redistribution structure 120. The first molding material 161 may cover the space between the first redistribution structure 120 and the first semiconductor stack S1, and the side surface of the first semiconductor stack S1. The first molding material 161 protects the first conductive posts 141, the second conductive posts 142, the first semiconductor stack S1, and the bonding pads 151 from the external environment, thereby ensuring electrical and mechanical stability of the semiconductor package 100A.

The second redistribution structure 130 may be disposed on the first semiconductor stack S1, the bonding pads 151, and the first molding material 161. The second redistribution structure 130 may contact the first semiconductor stack S1. The second redistribution structure 130 may include a first dielectric layer 131 and vias 132 within the first dielectric layer 131. In other embodiments, a second redistribution structure 130 comprising fewer or more vias 132 may be included within the scope of the present disclosure.

The first dielectric layer 131 may protect and insulate the vias 132. Third conductive posts 143 and second molding material 162 may be disposed on the upper surface of the first dielectric layer 131. A first semiconductor stack S1, bonding pads 151, and a first molding material 161 may be disposed on the lower surface of the first dielectric layer 131.

Each of the vias 132 may form signal, ground, and power routing paths for a corresponding second semiconductor die SD2 among the second semiconductor dies SD2 of the second semiconductor stack S2. The vias 132 may extend in the vertical direction within the first dielectric layer 131. The vias 132 may penetrate the first dielectric layer 131. The vias 132 may each have a shape in which the width in the horizontal direction decreases from the bottom to the top.

The third conductive posts 143 may be disposed on the second redistribution structure 130. Each of the third conductive posts 143 may be connected to a corresponding second semiconductor die SD2 among the second semiconductor dies SD2 of the second semiconductor stack S2. Each of the third conductive posts 143 may be disposed between a corresponding via 132 among the vias 132 of the second redistribution structure 130 and a corresponding second connection pad 153 among the second connection pads 153. Each of the third conductive posts 143 may electrically connect a corresponding second connection pad 153 among the second connection pads 153 to a corresponding via 132 among the vias 132 of the second redistribution structure 130. The side of the third conductive posts 143 may be surrounded by a second molding material 162. Each of the third conductive posts 143 may form signal, ground, and power routing paths for a corresponding second semiconductor die SD2 among the second semiconductor dies SD2 of the second semiconductor stack S2.

A second semiconductor stack S2 may be disposed on a second redistribution structure 130. The second semiconductor stack S2 may be disposed to be spaced apart from the second redistribution structure 130 in the vertical direction (Z direction). The second semiconductor stack S2 may include second semiconductor dies SD2 that are stacked in a vertical direction (Z direction) and adhesive members AM that are disposed alternately with the second semiconductor dies SD2. The number of second semiconductor dies SD2 included in the second semiconductor stack S2 may be determined by considering the function and performance of the semiconductor package 100A and the connection between the second redistribution structure 130 and the second semiconductor dies SD2. Although the drawings according to the present disclosure illustrate a second semiconductor stack S2 including two second semiconductor dies SD2, the present disclosure is not limited thereto, and a second semiconductor stack S2 including fewer or more second semiconductor dies SD2 may be included within the scope of the present disclosure. The second semiconductor dies SD2 may be stacked sequentially from below and with an offset in the first horizontal direction (X direction).

The second semiconductor die SD2 may include an active surface and a back side opposite the active surface. The second semiconductor die SD2 may be arranged with its active side facing the first redistribution structure 120. The second semiconductor die SD2 may include a device layer and a wiring layer on the active surface. The device layer may include an integrated circuit structure having integrated circuit regions. In embodiments, the integrated circuit structure may include at least one of an active device and a passive device. In embodiments, the integrated circuit structure may include a memory cell array, a transistor, a capacitor, an inductor, or a resistor. The wiring layer may be disposed on the device layer. The wiring layer may include signal wiring lines, power wiring lines, contact plugs, and intermetal dielectric IMD. In embodiments, the second semiconductor die SD2 may include a volatile or non-volatile memory die.

Each of the second semiconductor dies SD2 may include second connection pads 153 arranged on an active surface. The second connection pads 153 may be disposed in a row and conformally along the side of the second semiconductor die SD2. Each of the second connection pads 153 may be disposed between a corresponding third conductive post 143 among the third conductive posts 143 and the wiring of the second semiconductor die SD2. Each of the second connection pads 153 may electrically connect a corresponding third conductive post 143 among the third conductive posts 143 to the wiring of the second semiconductor die SD2. In embodiments, the second connection pads 153 may include at least one of copper, nickel, zinc, gold, silver, platinum, palladium, chromium, titanium, and alloys thereof.

The second molding material 162 may cover the third conductive posts 143 and the second semiconductor stack S2 on the second redistribution structure 130. The second molding material 162 may cover the space between the second redistribution structure 130 and the second semiconductor stack S2, and the side surface of the second semiconductor stack S2. The second molding material 162 protects the third conductive posts 143 and the second semiconductor stack S2 from the external environment, thereby ensuring electrical and mechanical stability of the semiconductor package 100A.

The third redistribution structure 170 may be disposed on the second semiconductor stack S2 and on the second molding material 162. The third redistribution structure 170 may include a second dielectric layer 171 and an alignment key pattern AK within the second dielectric layer 171. The align key pattern AK may include vias 181 and an align key 182. The align key pattern AK may include an align key 182 and may not include vias 181. In other embodiments, a third redistribution structure 170 comprising fewer or more align key patterns AKs may be included within the scope of the present disclosure.

The second dielectric layer 171 may protect and insulate the align key pattern AK. A second semiconductor stack S2 and a second molding material 162 may be disposed on the first surface of the second dielectric layer 171. The first surface of the second dielectric layer 171 may contact the second molding material 162. A metal layer 180 may be disposed on the second surface of the second dielectric layer 171. The second surface may be the opposite surface of the first surface. All of the second surface of the second dielectric layer 171 may be covered by the metal layer 180.

The align key pattern AK may be exposed from the first surface of the second dielectric layer 171. The align key pattern AK may penetrate the second dielectric layer 171. The align key pattern AK may extend from the metal layer 180. The align key 182 serves as a reference for the arrangement direction of the second semiconductor die SD2 in the process of forming a second semiconductor stack S2 by stacking the second semiconductor die SD2, thereby preventing the second semiconductor die SD2 from being misaligned. Vias 181 may be disposed between the metal layer 180 and the align key 182. The vias 181 may extend in the vertical direction within the second dielectric layer 171. The vias 181 may each have a shape in which the width in the horizontal direction decreases from the bottom to the top.

A metal layer 180 may be disposed on the third redistribution structure 170. The metal layer 180 may cover all of the upper surface of the third redistribution structure 170. The metal layer 180 may cover all of the second surface of the second dielectric layer 171. The metal layer 180 may include a third surface contacting the second dielectric layer 171 and a fourth surface opposite the third surface. The metal layer 180 may include a marking pattern M. The marking pattern M is a mark engraved on the metal layer 180 using a laser. The marking pattern M may function as an alignment mark or a recognition mark. The alignment mark may include various geometric shapes, such as a cross, a square, or a circle. The recognition mark may include, for example, product information such as letters or numbers, a barcode, a QR code, a manufacturer's name, a product model name, or a brand name. The marking pattern M may be a pattern recessed from the fourth surface. The metal layer 180 may have a first thickness T1 in the vertical direction (Z direction). In embodiments, the first thickness T1 may have a range of about 10 μm to about 40 μm. The marking pattern M may have a cross-sectional shape that is recessed in the vertical direction (Z direction) by a first depth D1 from the fourth surface of the metal layer 180. In embodiments, the first depth D1 may have a range of about 8 μm to about 38 μm. The first depth D1 may be less than the first thickness T1.

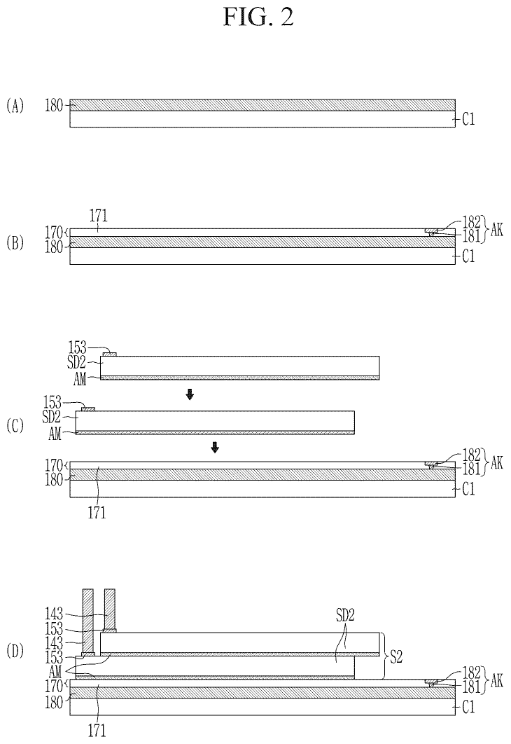

FIGS. 2 to 6 are cross-sectional views illustrating a method for manufacturing the semiconductor package 100A of FIG. 1.

Referring to step (A) of FIG. 2, a first carrier C1 may be provided. In embodiments, the first carrier C1 may include a silicon-based material, such as glass or silicon oxide, another material such as an organic material or aluminum oxide, or any combination of these materials. A metal layer 180 may be deposited on the first carrier C1. The metal layer 180 may be a seed metal layer. In embodiments, the metal layer 180 may be formed by performing a sputtering process or an electroless plating process. In embodiments, the metal layer 180 may include copper or a copper alloy. The metal layer 180 may be formed thicker than a typical seed metal layer to form a marking pattern M in a subsequent process. The metal layer 180 may have both the function of a seed metal layer and the function of an object on which a marking pattern M is engraved. According to the present disclosure, a seed metal layer, which is essentially deposited to form a redistribution via and a redistribution line of a redistribution structure, may be formed thickly, and a marking pattern may be formed on the thickly formed seed metal layer in a subsequent process. Accordingly, the process performed to form a dielectric layer for marking may be omitted in the manufacturing process of the semiconductor package 100A.

Referring to step (B) of FIG. 2, a third redistribution structure 170 may be formed on a metal layer 180. First, a second dielectric material layer 171 may be formed on the metal layer 180. In embodiments, the second dielectric material layer 171 may be deposited by performing a spin coating process. In embodiments, the second dielectric material layer 171 may include a photo imageable dielectric PID used in a redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. After this, an align key pattern AK may be formed within the second dielectric layer 171. In embodiments, the align key pattern AK may be formed by performing a photoresist process and an etching process on the second dielectric layer 171 to form openings, and performing an electrolytic plating process using the metal layer 180 as a seed metal layer. In embodiments, the align key pattern AK may include copper or a copper alloy. The vias 181 of the align key pattern AK may each have a shape in which the width in the horizontal direction increases from the bottom to the top. In the semiconductor package 100A that is the final product, the vias 181 of the alignment key pattern AK may have a shape in which the width in the horizontal direction decreases from the bottom to the top.

Referring to step (C) of FIG. 2, the second semiconductor dies SD2 may be aligned at the positions where the second semiconductor dies SD2 are to be disposed based on the alignment key pattern AK. After this, second semiconductor dies SD2 may be sequentially stacked on the second dielectric layer 171 using adhesive members AM. The second semiconductor dies SD2 may be stacked with an offset in the horizontal direction (X direction) so that each of the second connection pads 153 is exposed. In embodiments, the adhesive members AM may include a die attach film DAF.

Referring to step (D) of FIG. 2, third conductive posts 143 may be formed on the second connection pads 153 of each of the second semiconductor dies SD2. Each of the third conductive posts 143 may be formed to be disposed on a corresponding second connection pad 153 among the second connection pads 153. The third conductive posts 143 may be formed by additionally depositing photoresist on the second semiconductor dies SD2, selectively exposing and developing the photoresist to form a photoresist pattern including openings, and filling the openings with a conductive material. In embodiments, the third conductive posts 143 may be formed by performing an electrolytic plating process after forming a seed metal layer. In embodiments, the third conductive posts 143 may comprise copper or a copper alloy.

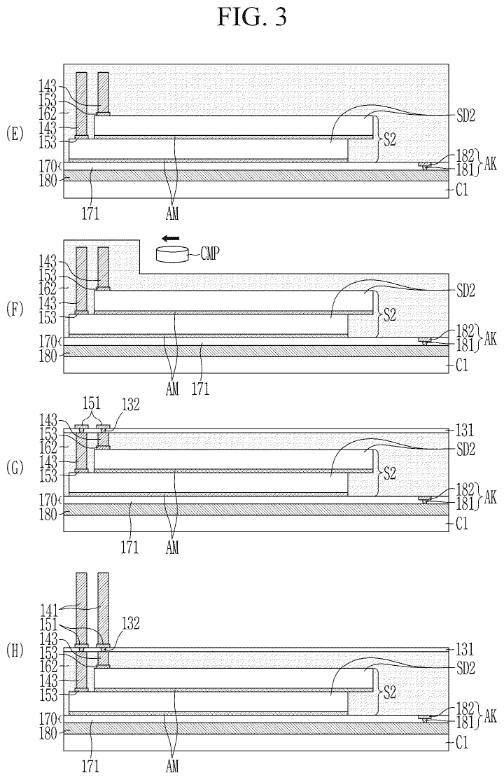

Referring to step (E) of FIG. 3, the second semiconductor stack S2 and the third conductive posts 143 may be molded with the second molding material 162 on the third redistribution structure 170. In embodiments, the process of molding with the second molding material 162 may include a compression molding or transfer molding process. In embodiments, the second molding material 162 may include an epoxy molding compound EMC.

Referring to step (F) of FIG. 3, a chemical mechanical polishing CMP process may be performed. After performing the chemical mechanical polishing CMP process, the ends of the third conductive posts 143 may be exposed.

Referring to step (G) of FIG. 3, a second redistribution structure 130 may be formed on the third conductive posts 143 and on the second molding material 162. First, a first dielectric layer 131 may be formed on the third conductive posts 143 and on the second molding material 162. In embodiments, the first dielectric layer 131 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, vias 132 and bonding pads 151 may be formed by performing a photoresist process and an etching process on the first dielectric layer 131 to form openings, and filling the openings with a conductive material. In embodiments, the vias 132 and bonding pads 151 may each be formed by performing an electrolytic plating process after forming a seed metal layer. In embodiments, the vias 132 and bonding pads 151 may each comprise copper or a copper alloy. The vias 132 may each have a shape in which the width in the horizontal direction increases from the bottom to the top. In the semiconductor package 100A that is the final product, the vias 132 may have a shape in which the width in the horizontal direction decreases from the bottom to the top.

Referring to step (H) of FIG. 3, first conductive posts 141 may be formed on bonding pads 151. Each of the first conductive posts 141 among the first conductive posts 141 may be formed to be disposed on a corresponding bonding pad 151 among the bonding pads 151. The first conductive posts 141 may be formed by additionally depositing a photoresist on the second redistribution structure 130, selectively exposing and developing the photoresist to form a photoresist pattern including openings, and filling the openings with a conductive material. In embodiments, the first conductive posts 141 may be formed by performing an electrolytic plating process after forming a seed metal layer. In embodiments, the first conductive posts 141 may comprise copper or a copper alloy.

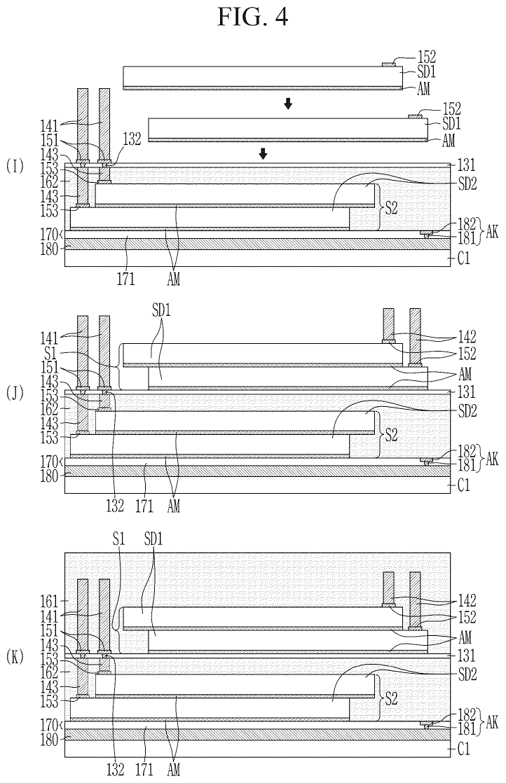

Referring to step (I) of FIG. 4, first semiconductor dies SD1 may be sequentially stacked on a first dielectric layer 131 using adhesive members AM. The first semiconductor dies SD1 may be stacked with an offset in the horizontal direction (X direction) so that each of the first connection pads 152 is exposed. In embodiments, the adhesive members AM may include a die attach film DAF.

Referring to step (J) of FIG. 4, second conductive posts 142 may be formed on the first connection pads 152 of each of the first semiconductor dies SD1. Each of the second conductive posts 142 may be formed to be disposed on a corresponding first connecting pad 152 among the first connecting pads 152. The second conductive posts 142 may be formed by additionally depositing photoresist on the first semiconductor dies SD1, selectively exposing and developing the photoresist to form a photoresist pattern including openings, and filling the openings with a conductive material. In embodiments, the second conductive posts 142 may be formed by performing an electrolytic plating process after forming a seed metal layer. In embodiments, the second conductive posts 142 may comprise copper or a copper alloy.

Referring to step (K) of FIG. 4, the first semiconductor stack S1, the first conductive posts 141, and the second conductive posts 142 may be molded with the first molding material 161 on the second redistribution structure 130. In embodiments, the process of molding with the first molding material 161 may include a compression molding or transfer molding process. In embodiments, the first molding material 161 may include an epoxy molding compound EMC.

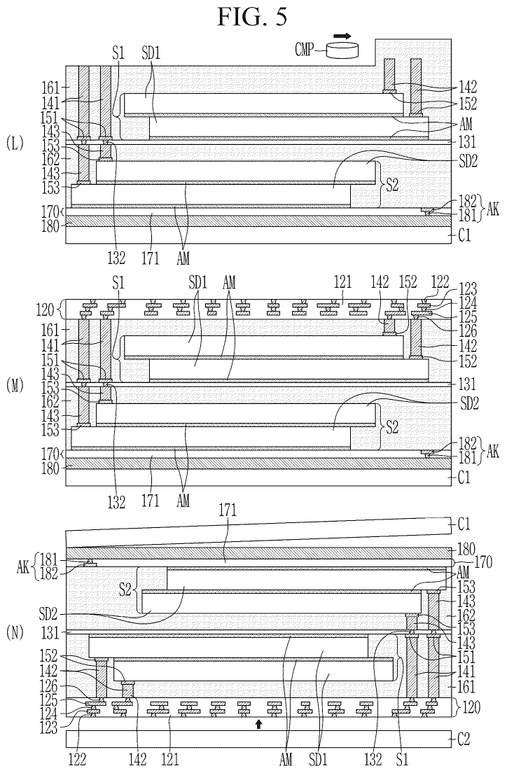

Referring to step (L) of FIG. 5, a chemical mechanical polishing CMP process may be performed. After performing the chemical mechanical polishing CMP process, the ends of the first conductive posts 141 and the ends of the second conductive posts 142 may be exposed.

Referring to step (M) of FIG. 5, a first redistribution structure 120 may be formed on the first conductive posts 141, the second conductive posts 142, and on the first molding material 161. After a dielectric 121 is deposited on the first conductive posts 141, the second conductive posts 142, and the first molding material 161, the dielectric 121 is selectively etched to form openings, and the openings are filled with a conductive material, thereby forming third redistribution vias 126, second redistribution lines 125, second redistribution vias 124, first redistribution lines 123, and first redistribution vias 122 sequentially from the bottom.

In embodiments, the dielectric 121 may be deposited by performing a spin coating process. In embodiments, the dielectric 121 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, a photoresist process and an etching process may be performed to etch the dielectric 121 and form openings in the dielectric 121. In embodiments, the first redistribution vias 122, the first redistribution lines 123, the second redistribution vias 124, the second redistribution lines 125, and the third redistribution vias 126 may each be formed by performing an electrolytic plating process after forming a seed metal layer. In embodiments, the first redistribution vias 122, the first redistribution lines 123, the second redistribution vias 124, the second redistribution lines 125, and the third redistribution vias 126 may each include at least one of copper, aluminum, tungsten, nickel, gold, tin, titanium, and alloys thereof.

Since the first redistribution vias 122, the second redistribution vias 124, and the third redistribution vias 126 are formed later by the chip first process, the first redistribution vias 122, the second redistribution vias 124, and the third redistribution vias 126 may each have a shape in which the width in the horizontal direction increases from the bottom to the top. In the semiconductor package (100A) that is the final product, the first redistribution vias 122, the second redistribution vias 124, and the third redistribution vias 126 may each have a shape in which the width in the horizontal direction decreases from the bottom to the top.

Referring to step (N) of FIG. 5, the first carrier C1 may be removed and a second carrier C2 may be attached to the first redistribution structure 120.

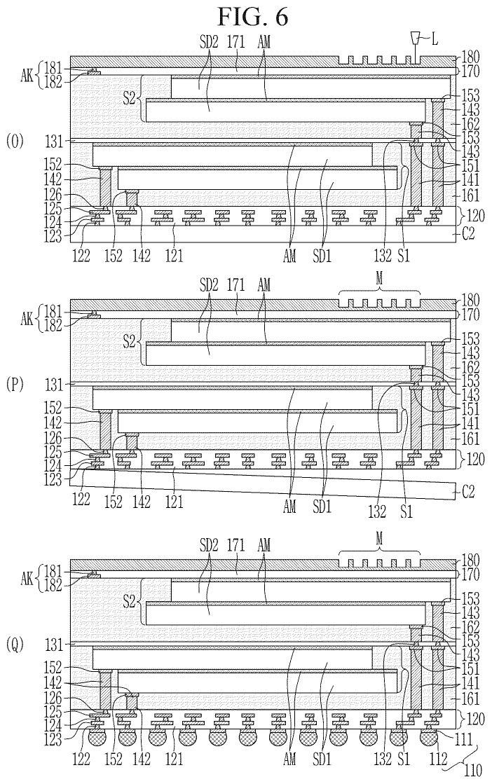

Referring to step (O) of FIG. 6, recesses may be formed according to a marking pattern M to be formed using a laser L. Since the marking pattern M is formed on a metal layer 180 having a relatively higher light reflectance than the light reflectance of the dielectric layer for marking, the semiconductor package 100A may have a marking pattern M with improved visibility.

Referring to step (P) of FIG. 6, the second carrier C2 may be removed.

Referring to step (Q) of FIG. 6, an external connection structure 110 may be formed on the first redistribution structure 120. Conductive pads 111 may be formed on the first redistribution vias 122 of the first redistribution structure 120. In embodiments, the conductive pads 111 may include at least one of copper, nickel, zinc, gold, silver, platinum, palladium, chromium, titanium, and alloys thereof. In embodiments, the conductive pads 111 may be formed by performing a sputtering process or by performing an electrolytic plating process after forming a seed metal layer. After this, an external connecting member 112 may be formed on each of the conductive pads 111. In embodiments, the external connecting members 112 may include at least one of tin, silver, lead, nickel, copper, and alloys thereof.

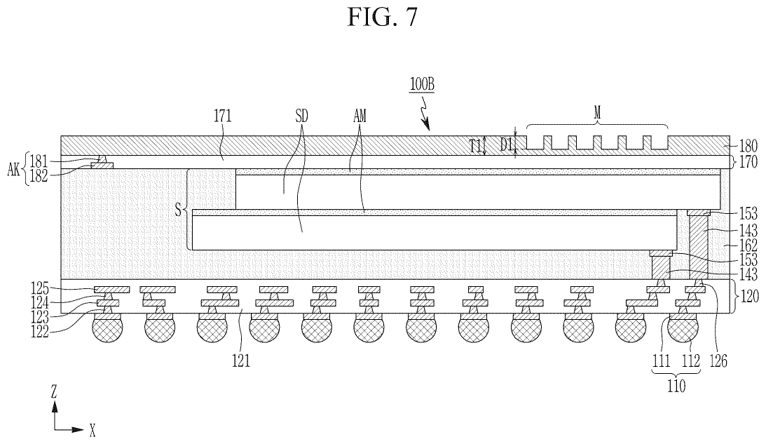

FIG. 7 is a cross-sectional view illustrating a semiconductor package 100B of embodiments.

Referring to FIG. 7, the semiconductor package 100B may include an external connection structure 110, a front side redistribution structure 120, conductive posts 143, a semiconductor stack S, a molding material 162, a back side redistribution structure 170, and a metal layer 180.

The conductive posts 143 may be disposed on the front side redistribution structure 120. Each of the conductive posts 143 may be connected to a corresponding semiconductor die SD among the semiconductor dies SD of the semiconductor stack S. Each of the conductive posts 143 may be disposed between a corresponding third redistribution via 126 among the third redistribution vias 126 of the front side redistribution structure 120 and a corresponding connection pad 153 among the connection pads 153. Each of the conductive posts 143 may electrically connect a corresponding connection pad 153 among the connection pads 153 to a corresponding third redistribution via 126 among the third redistribution vias 126 of the front side redistribution structure 120. The sides of the conductive posts 143 may be surrounded by molding material 162. Each of the conductive posts 143 may form signal, ground, and power routing paths for a corresponding semiconductor die SD among the semiconductor dies SD of the semiconductor stack S.

The semiconductor stack S may be disposed on the front side redistribution structure 120. The semiconductor stack S may be disposed to be spaced apart from the front side redistribution structure 120 in the vertical direction (Z direction). The semiconductor stack S may be disposed to be spaced apart in the vertical direction (Z direction) from the front side redistribution structure 120. A semiconductor stack S may include semiconductor dies SD stacked in a vertical direction (Z direction) and adhesive members AM arranged alternately with the semiconductor dies SD. The number of semiconductor dies SD included in the semiconductor stack S may be determined by considering the function and performance of the semiconductor package 100B and the connection between the front side redistribution structure 120 and the semiconductor dies SD. Although the drawings according to the present disclosure illustrate a semiconductor stack S including two semiconductor dies SD, the present disclosure is not limited thereto, and a semiconductor stack S including fewer or more semiconductor dies SD may be included in the present disclosure. Semiconductor dies SD may be stacked sequentially from below and with an offset in the first horizontal direction (X direction).

Each of the semiconductor dies SD of the semiconductor stack S may include connection pads 153 arranged on an active surface. The connection pads 153 may be disposed in a row and conformally along the side of the semiconductor die SD. Each of the connection pads 153 may be disposed between a corresponding conductive post 143 among the conductive posts 143 and the wiring of the semiconductor die SD. Each of the connection pads 153 may electrically connect a corresponding conductive post 143 among the conductive posts 143 to the wiring of the semiconductor die SD. In embodiments, the connection pads 153 may include at least one of copper, nickel, zinc, gold, silver, platinum, palladium, chromium, titanium, and alloys thereof.

The molding material 162 may cover the conductive posts 143 and the semiconductor stack S on the front side redistribution structure 120. The molding material 162 may cover the space between the front side redistribution structure 120 and the semiconductor stack S, and the side of the semiconductor stack S. The molding material 162 protects the conductive posts 143 and the semiconductor stack S from the external environment, thereby ensuring the electrical and mechanical stability of the semiconductor package 100B.

The back side redistribution structure 170 may be disposed on the semiconductor stack S and on the molding material 162. The back side redistribution structure 170 may include a dielectric layer 171 and an alignment key pattern AK within the dielectric layer 171. The align key pattern AK may include vias 181 and an align key 182. The align key pattern AK may include the align key 182 and may not include vias 181. In other embodiments, a back side redistribution structure 170 including fewer or more align key patterns AK may be included within the scope of the present disclosure.

The dielectric layer 171 may protect and insulate the align key pattern AK. A semiconductor stack S and a molding material 162 may be disposed on the first surface of the dielectric layer 171. The first surface of the dielectric layer 171 may contact the molding material 162. A metal layer 180 may be disposed on the second surface of the dielectric layer 171. The second surface may be the opposite surface of the first surface. All of the second surface of the dielectric layer 171 may be covered by the metal layer 180.

The align key pattern AK may be exposed from the first surface of the dielectric layer 171. The align key pattern AK may penetrate the dielectric layer 171. The align key pattern AK may extend from the metal layer 180. The align key 182 serves as a reference for the arrangement direction of the semiconductor dies SD in the process of forming a semiconductor stack S by stacking the semiconductor dies SD, thereby preventing the semiconductor dies SD from being misaligned. Vias 181 may be disposed between the metal layer 180 and the align key 182. The vias 181 may extend in the vertical direction within the dielectric layer 171. The vias 181 may each have a shape in which the width in the horizontal direction decreases from the bottom to the top.

A metal layer 180 may be disposed on the back side redistribution structure 170. The metal layer 180 may cover all of the upper surface of the back side redistribution structure 170. The metal layer 180 may cover all of the second surface of the dielectric layer 171. The metal layer 180 may include a third surface contacting the dielectric layer 171 and a fourth surface opposite the third surface. The metal layer 180 may include a marking pattern M. The marking pattern M is a mark engraved on the metal layer 180 using a laser. The marking pattern M may function as an alignment mark or a recognition mark. The alignment mark may include various geometric shapes, such as a cross, a square, or a circle. The recognition mark may include, for example, product information such as letters or numbers, a barcode, a QR code, a manufacturer's name, a product model name, or a brand name. The marking pattern M may be a pattern recessed from the fourth surface. The metal layer 180 may have a first thickness T1 in the vertical direction (Z direction). In embodiments, the first thickness T1 may have a range of about 10 μm to about 40 μm. The marking pattern M may have a cross-sectional shape that is recessed in the vertical direction (Z direction) by a first depth D1 from the fourth surface of the metal layer 180. In embodiments, the first depth D1 may have a range of about 8 μm to about 38 μm. The first depth D1 may be less than the first thickness T1.

For contents other than those described for the semiconductor package 100B of embodiments in FIG. 7, the contents described for the semiconductor package 100A in FIG. 1 may be applied.

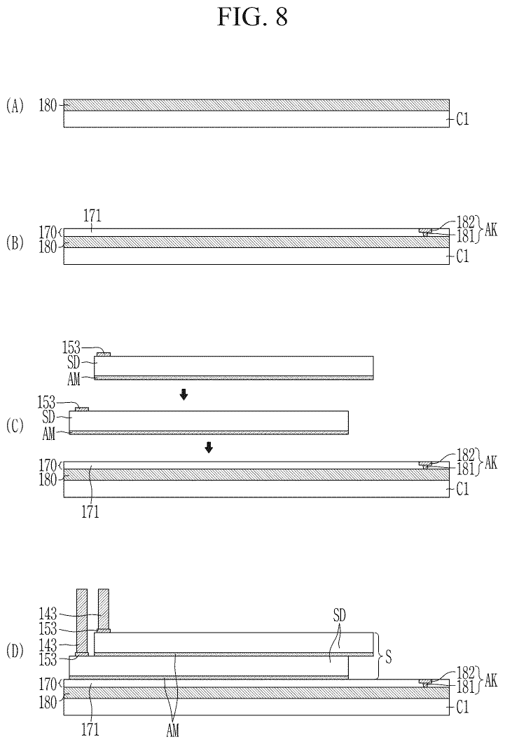

FIGS. 8 to 10 are cross-sectional views illustrating a method for manufacturing the semiconductor package 100B of FIG. 7.

Referring to step (A) of FIG. 8, a first carrier C1 may be provided. In embodiments, the first carrier C1 may include a silicon-based material, such as glass or silicon oxide, another material such as an organic material or aluminum oxide, or any combination of these materials. A metal layer 180 may be deposited on the first carrier C1. The metal layer 180 may be a seed metal layer. In embodiments, the metal layer 180 may be formed by performing a sputtering process or an electroless plating process. In embodiments, the metal layer 180 may include copper or a copper alloy. The metal layer 180 may be formed thicker than a typical seed metal layer to form a marking pattern M in a subsequent process. The metal layer 180 may have both the function of a seed metal layer and the function of an object on which a marking pattern M is engraved. According to the present disclosure, a seed metal layer, which is essentially deposited to form a redistribution via and a redistribution line of a redistribution structure, may be formed thickly, and a marking pattern may be formed on the thickly formed seed metal layer in a subsequent process. Accordingly, the process performed to form a dielectric layer for marking may be omitted in the manufacturing process of the semiconductor package 100B.

Referring to step (B) of FIG. 8, a back side redistribution structure 170 may be formed on a metal layer 180. First, a dielectric layer 171 may be formed on a metal layer 180. In embodiments, the dielectric layer 171 may be deposited by performing a spin coating process. In embodiments, the dielectric layer 171 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. After this, an alignment key pattern AK may be formed within the dielectric layer 171. In embodiments, the align key pattern AK may be formed by performing a photoresist process and an etching process on the dielectric layer 171 to form openings, and performing an electrolytic plating process using the metal layer 180 as a seed metal layer. In embodiments, the align key pattern AK may include copper or a copper alloy. The vias 181 of the align key pattern AK may each have a shape in which the width in the horizontal direction increases from the bottom to the top. In the semiconductor package 100B that is the final product, the vias 181 of the alignment key pattern AK may have a shape in which the width in the horizontal direction decreases from the bottom to the top.

Referring to step (C) of FIG. 8, the semiconductor dies SD may be aligned at the positions where the semiconductor dies SD are to be disposed based on the alignment key pattern AK. After this, semiconductor dies SD may be sequentially stacked on the dielectric layer 171 using adhesive members AM. The semiconductor dies SD may be stacked with an offset in the horizontal direction (X direction) so that each of the connection pads 153 is exposed. In embodiments, the adhesive members AM may include a die attach film DAF.

Referring to step (D) of FIG. 8, conductive posts 143 may be formed on each of the connection pads 153 of the semiconductor dies SD. Each of the conductive posts 143 may be formed to be disposed on a corresponding connecting pad 153 among the connecting pads 153. The conductive posts 143 may be formed by additionally depositing photoresist on semiconductor dies SD, selectively exposing and developing the photoresist to form a photoresist pattern including openings, and filling the openings with a conductive material. In embodiments, the conductive posts 143 may be formed by performing an electrolytic plating process after forming a seed metal layer. In embodiments, the conductive posts 143 may comprise copper or a copper alloy.

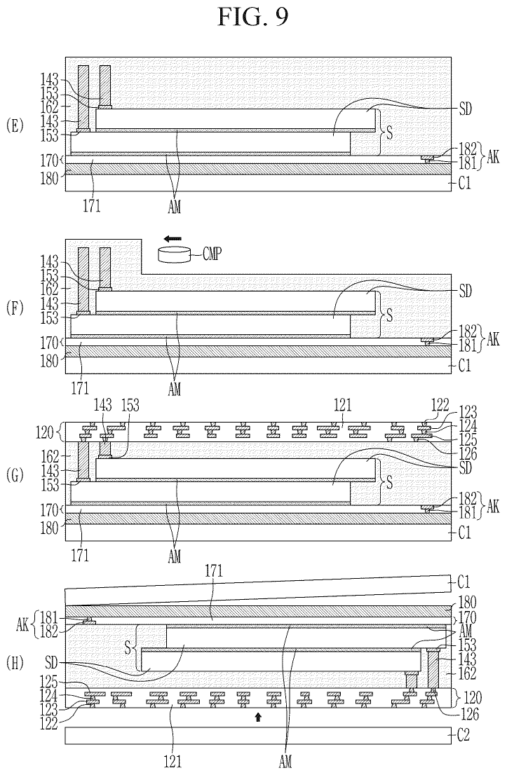

Referring to step (E) of FIG. 9, on the back side redistribution structure 170, the semiconductor stack S and conductive posts 143 may be molded with a molding material 162. In embodiments, the process of molding with the molding material 162 may include a compression molding or transfer molding process. In embodiments, the molding material 162 may include an epoxy molding compound EMC.

Referring to step (F) of FIG. 9, a chemical mechanical polishing CMP process may be performed. After performing the chemical mechanical polishing CMP process, the ends of the conductive posts 143 may be exposed.

Referring to step (G) of FIG. 9, a front side redistribution structure 120 may be formed on the conductive posts 143 and on the molding material 162. After forming a dielectric 121 on the conductive posts 143 and the molding material 162, the dielectric 121 is selectively etched to form openings, and the openings are filled with a conductive material, thereby forming third redistribution vias 126, second redistribution lines 125, second redistribution vias 124, first redistribution lines 123, and first redistribution vias 122 sequentially from the bottom.

In embodiments, the dielectric 121 may be deposited by performing a spin coating process. In embodiments, the dielectric 121 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, a photoresist process and an etching process may be performed to etch the dielectric 121 and form openings in the dielectric 121. In embodiments, the first redistribution vias 122, the first redistribution lines 123, the second redistribution vias 124, the second redistribution lines 125, and the third redistribution vias 126 may each be formed by performing an electrolytic plating process after forming a seed metal layer. In embodiments, the first redistribution vias 122, the first redistribution lines 123, the second redistribution vias 124, the second redistribution lines 125, and the third redistribution vias 126 may each include at least one of copper, aluminum, tungsten, nickel, gold, tin, titanium, and alloys thereof.

Since the first redistribution vias 122, the second redistribution vias 124, and the third redistribution vias 126 are formed later by the chip first process, the first redistribution vias 122, the second redistribution vias 124, and the third redistribution vias 126 may each have a shape in which the width in the horizontal direction increases from the bottom to the top. In the semiconductor package 100B that is the final product, the first redistribution vias 122, the second redistribution vias 124, and the third redistribution vias 126 may each have a shape in which the width in the horizontal direction decreases from the bottom to the top.

Referring to step (H) of FIG. 9, the first carrier C1 may be removed and a second carrier C2 may be attached to the front side redistribution structure 120.

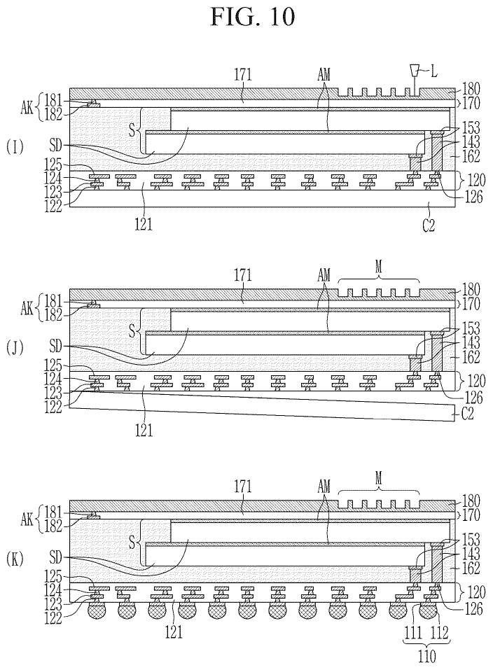

Referring to step (I) of FIG. 10, recesses may be formed according to a marking pattern M to be formed using a laser L. Since the marking pattern M is formed on a metal layer 180 having a relatively higher light reflectance than the light reflectance of the dielectric layer for marking, the semiconductor package 100B may have a marking pattern M with improved visibility.

Referring to step (J) of FIG. 10, the second carrier C2 may be removed.

Referring to step (K) of FIG. 10, an external connection structure 110 may be formed on a front side redistribution structure 120. Conductive pads 111 may be formed on the first redistribution vias 122 of the front side redistribution structure 120. In embodiments, the conductive pads 111 may include at least one of copper, nickel, zinc, gold, silver, platinum, palladium, chromium, titanium, and alloys thereof. In embodiments, the conductive pads 111 may be formed by performing a sputtering process or by performing an electrolytic plating process after forming a seed metal layer. After this, an external connecting member 112 may be formed on each of the conductive pads 111. In embodiments, the external connecting members 112 may include at least one of tin, silver, lead, nickel, copper, and alloys thereof.

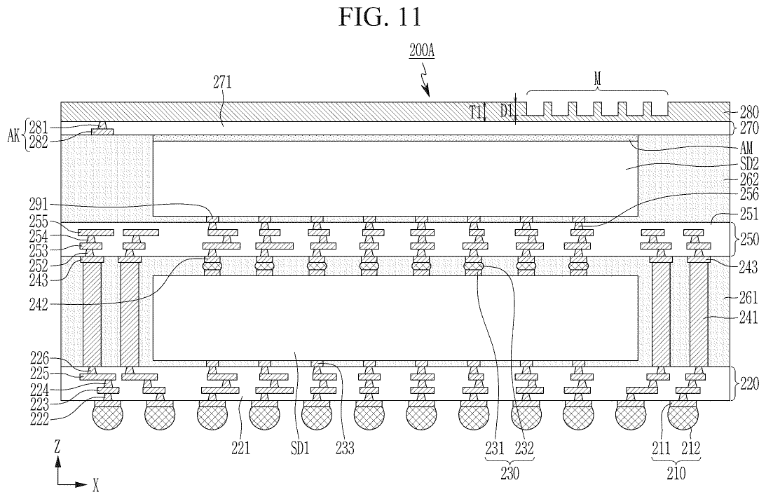

FIG. 11 is a cross-sectional view illustrating a semiconductor package 200A of embodiments.

Referring to FIG. 11, a semiconductor package 200A may include an external connection structure 210, a first redistribution structure 220, conductive posts 241, a first semiconductor die SD1, a bump structure 230, first bonding pads 242, second bonding pads 243, a first molding material 261, a second redistribution structure 250, a second semiconductor die SD2, an adhesive member AM, a third redistribution structure 270, and a metal layer 280. In embodiments, the semiconductor package 200A may include a package on package PoP. In embodiments, the semiconductor package 200A may be a semiconductor package manufactured based on fan-out wafer level package FOWLP or fan-out panel level package FOPLP technology. In embodiments according to the present disclosure, a semiconductor package 200A including a first semiconductor die SD1 and a second semiconductor die SD2 is illustrated and described, but is not limited thereto, and a semiconductor package 200A including more semiconductor dies SD may be included in the present disclosure.

The external connection structure 210 may be disposed on the lower surface of the first redistribution structure 220. The external connection structure 210 may include conductive pads 211 and external connection members 212. Each of the conductive pads 211 may electrically connect a corresponding first redistribution via 222 among the first redistribution vias 222 of the first redistribution structure 220 to a corresponding external connection member 212 among the external connection members 212. External connection members 212 may electrically connect the semiconductor package 200A to an external device (not shown).

The first redistribution structure 220 may be disposed on the external connection structure 210. The first redistribution structure 220 may include a dielectric 221, and first redistribution vias 222, first redistribution lines 223, second redistribution vias 224, second redistribution lines 225, and third redistribution vias 226 within the dielectric 221. In other embodiments, a first redistribution structure 220 including fewer or more redistribution lines and redistribution vias may be included within the scope of the present disclosure.

The dielectric 221 may protect and insulate the first redistribution vias 222, the first redistribution lines 223, the second redistribution vias 224, the second redistribution lines 225, and the third redistribution vias 226. First conductive posts 241, second conductive posts 242, and first molding material 261 may be disposed on the upper surface of the dielectric 221. Conductive pads 211 may be disposed on the lower surface of the dielectric 221.

The first redistribution vias 222, the first redistribution lines 223, the second redistribution vias 224, the second redistribution lines 225, and the third redistribution vias 226 are disposed sequentially from below and may form signal, ground, and power routing paths. The first redistribution lines 223 and the second redistribution lines 225 may extend in the horizontal direction within the dielectric 221. The first redistribution vias 222, the second redistribution vias 224, and the third redistribution vias 226 may extend in the vertical direction within the dielectric 221. The first redistribution vias 222, the second redistribution vias 224, and the third redistribution vias 226 may each have a shape in which the width in the horizontal direction decreases from the bottom to the top.

The conductive posts 241 may be disposed on the first redistribution structure 220. Each of the conductive posts 241 may be disposed between the first redistribution structure 220 and the second redistribution structure 250. Each of the conductive posts 241 may be disposed between a corresponding third redistribution via 226 among the third redistribution vias 226 of the first redistribution structure 220 and a corresponding bonding pad 243 among the bonding pads 243. Each of the conductive posts 241 may electrically connect a corresponding bonding pad 243 among the bonding pads 243 to a corresponding third redistribution via 226 among the third redistribution vias 226 of the first redistribution structure 220. The sides of the conductive posts 241 may be surrounded by a first molding material 261. Each of the conductive posts 241 may form signal, ground, and power routing paths for the second semiconductor die SD2.

A first semiconductor die SD1 may be disposed on a first redistribution structure 220. The first semiconductor die SD1 may be electrically connected to the first redistribution structure 220 by connection terminals 233. The first semiconductor die SD1 may include an active surface and a back side opposite the active surface. The first semiconductor die SD1 may be disposed so that its active surface faces the first redistribution structure 120. The first semiconductor die SD1 may include a device layer and a wiring layer on the active surface. The device layer may include an integrated circuit structure having integrated circuit regions. In embodiments, the integrated circuit structure may include at least one of an active device and a passive device. In embodiments, the integrated circuit structure may include a memory cell array, a transistor, a capacitor, an inductor, or a resistor. The wiring layer may be disposed on the device layer. The wiring layer may include signal wiring lines, power wiring lines, contact plugs, and intermetal dielectric IMD. In embodiments, the first semiconductor die SD1 may include a logic die. In embodiments, the first semiconductor die SD1 may include a System on Chip SoC. In embodiments, the first semiconductor die SD1 may include an Application Processor AP. In embodiments, the first semiconductor die SD1 may include at least one of a Central Processing Unit CPU, a Graphic Processing Unit GPU, a signal processor, a network processor, and a codec.

Bump structures 230 may be disposed between the first semiconductor die SD1 and the first bonding pads 242. Each of the bump structures 230 is disposed on a corresponding first bonding pad 242 among the first bonding pads 242, and may electrically connect the wiring of the first semiconductor die SD1 to the corresponding first bonding pad 242 among the first bonding pads 242. Each of the bump structures 230 may include a bump pillar 231 and a solder ball 232. In embodiments, the bump structures 230 may include micro bumps.

The first bonding pads 242 may be disposed between the bump structures 230 and the second redistribution structure 250. Each of the first bonding pads 242 is disposed between a corresponding first redistribution via 252 among the first redistribution vias 252 of the second redistribution structures 250 and a corresponding bump structure 230 among the bump structures 230, and may electrically connect a corresponding first redistribution via 252 among the first redistribution vias 252 to a corresponding bump structure 230 among the bump structures 230.

Second bonding pads 243 may be disposed between the conductive posts 241 and the second redistribution structure 250. Each of the second bonding pads 243 is disposed between a corresponding first redistribution via 252 among the first redistribution vias 252 of the second redistribution structure 250 and a corresponding conductive post 241 among the conductive posts 241, and may electrically connect a corresponding first redistribution via 252 among the first redistribution vias 252 to a corresponding conductive post 241 among the conductive posts 241.

The first molding material 261 may cover the first semiconductor die SD1, the conductive posts 241, the first bonding pads 242, and the second bonding pads 243 on the first redistribution structure 220. The first molding material 261 protects the first semiconductor die SD1, the conductive posts 241, the first bonding pads 242, and the second bonding pads 243 from the external environment, thereby ensuring electrical and mechanical stability of the semiconductor package 200A.

The second redistribution structure 250 may be disposed on the first molding material 261, on the first bonding pads 242, and on the second bonding pads 243. The second redistribution structure 250 may include a dielectric (a first dielectric layer) 251, and first redistribution vias 252, first redistribution lines 253, second redistribution vias 254, second redistribution lines 255, and third redistribution vias 256 within the dielectric 251. In other embodiments, a second redistribution structure 250 including fewer or more redistribution lines and redistribution vias may be included within the scope of the present disclosure.

The dielectric 251 may protect and insulate the first redistribution vias 252, the first redistribution lines 253, the second redistribution vias 254, the second redistribution lines 255, and the third redistribution vias 256. Connection terminals 291 and a second molding material 262 may be disposed on the upper surface of the dielectric 251. A first molding material 261, first bonding pads 242 and second bonding pads 243 may be disposed on the lower surface of the dielectric 251.

The first redistribution vias 252, the first redistribution lines 253, the second redistribution vias 254, the second redistribution lines 255, and the third redistribution vias 256 are disposed sequentially from below and may form signal, ground, and power routing paths. The first redistribution lines 253 and the second redistribution lines 255 may extend in the horizontal direction within the dielectric 251. The first redistribution vias 252, the second redistribution vias 254, and the third redistribution vias 256 may extend in the vertical direction within the dielectric 251. The first redistribution vias 252, the second redistribution vias 254, and the third redistribution vias 256 may each have a shape in which the width in the horizontal direction decreases from the bottom to the top.

A second semiconductor die SD2 may be disposed on the second redistribution structure 250. The second semiconductor die SD2 may be electrically connected to the second redistribution structure 250 by a connection terminal 291. The second semiconductor die SD2 may be a plurality of semiconductor dies. In embodiments, the second semiconductor die SD2 may include a single chip, such as a DRAM, or multiple chips, such as a High Bandwidth Memory HBM.

The adhesive member AM may attach the second semiconductor die SD2 to the third redistribution structure 270. In embodiments, the adhesive member AM may include a die attach film DAF.

The second molding material 262 may cover the second semiconductor die SD2 and the adhesive member AM on the second redistribution structure 250. The second molding material 162 protects the second semiconductor die SD2 and the adhesive member AM from the external environment, thereby ensuring electrical and mechanical stability of the semiconductor package 200A.

The third redistribution structure 270 may be disposed on the adhesive member AM and on the second molding material 262. The third redistribution structure 270 may include a dielectric layer (a second dielectric layer) 271 and an align key pattern AK within the dielectric layer 271. The align key pattern AK may include vias 281 and an align key 282. The align key pattern AK may include an align key 282 and may not include vias 281. In other embodiments, a third redistribution structure 270 comprising fewer or more align key patterns AK may be included within the scope of the present disclosure.

The dielectric layer 271 may protect and insulate the alignment key pattern AK. An adhesive member AM and a second molding material 262 may be disposed on the first surface of the dielectric layer 271. The first surface of the dielectric layer 171 may contact the second molding material 262. A metal layer 280 may be disposed on the second surface of the dielectric layer 271. The second surface may be the opposite surface of the first surface. All of the second surface of the dielectric layer 271 may be covered by the metal layer 280.

The align key pattern AK may be exposed from the first surface of the dielectric layer 271. The align key pattern AK may penetrate the dielectric layer 271. The align key pattern AK may extend from the metal layer 280. The alignment key 282 serves as a reference for the arrangement direction of the second semiconductor die SD2 in the process of attaching the second semiconductor die SD2 to the third redistribution structure 270, thereby preventing the second semiconductor die SD2 from being misaligned. Vias 281 may be disposed between the metal layer 280 and the align key 282. The vias 281 may extend in the vertical direction within the dielectric layer 271. The vias 282 may each have a shape in which the width in the horizontal direction decreases from the bottom to the top.

A metal layer 280 may be disposed on the third redistribution structure 270. The metal layer 280 may cover all of the upper surface of the third redistribution structure 270. The metal layer 280 may cover all of the second surface of the dielectric layer 271. The metal layer 280 may include a third surface contacting the dielectric layer 271 and a fourth surface opposite the third surface. The metal layer 280 may include a marking pattern M. The marking pattern M is a mark engraved on the metal layer 280 using a laser. The marking pattern M may function as an alignment mark or a recognition mark. The alignment mark may include various geometric shapes, such as a cross, a square, or a circle. The recognition mark may include, for example, product information such as letters or numbers, a barcode, a QR code, a manufacturer's name, a product model name, or a brand name. The marking pattern M may be a pattern recessed from the fourth surface. The metal layer 280 may have a first thickness T1 in the vertical direction (Z direction). In embodiments, the first thickness T1 may have a range of about 10 μm to about 40 μm. The marking pattern M may have a cross-sectional shape that is recessed in the vertical direction (Z direction) by a first depth D1 from the fourth surface of the metal layer 280. In embodiments, the first depth D1 may have a range of about 8 μm to about 38 μm. The first depth D1 may be less than the first thickness T1.

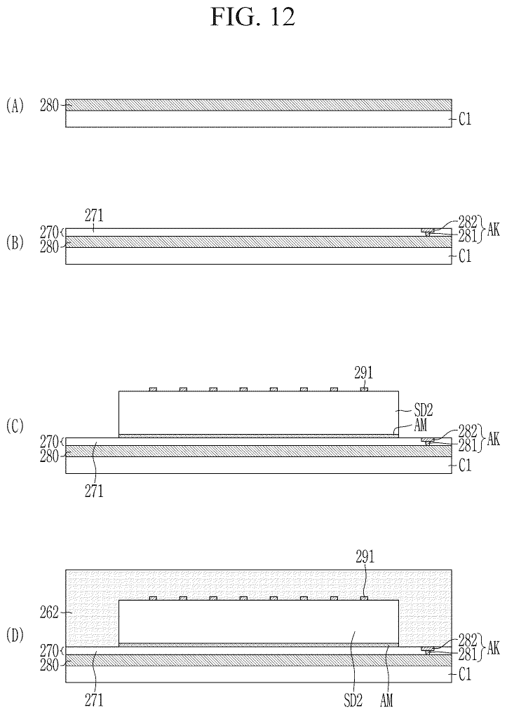

FIGS. 12 to 16 are cross-sectional views illustrating a method for manufacturing the semiconductor package 200A of FIG. 11.

Referring to step (A) of FIG. 12, a first carrier C1 may be provided. In embodiments, the first carrier C1 may include a silicon-based material, such as glass or silicon oxide, another material such as an organic material or aluminum oxide, or any combination of these materials. A metal layer 280 may be deposited on the first carrier C1. The metal layer 280 may be a seed metal layer. In embodiments, the metal layer 280 may be formed by performing a sputtering process or an electroless plating process. In embodiments, the metal layer 280 may include copper or a copper alloy. The metal layer 280 may be formed thicker than a typical seed metal layer to form a marking pattern M in a subsequent process. The metal layer 280 may have both the function of a seed metal layer and the function of an object on which a marking pattern M is engraved. According to the present disclosure, a seed metal layer, which is essentially deposited to form a redistribution via and a redistribution line of a redistribution structure, may be formed thickly, and a marking pattern may be formed on the thickly formed seed metal layer in a subsequent process. Accordingly, the process performed to form a dielectric layer for marking may be omitted in the manufacturing process of the semiconductor package 200A.

Referring to step (B) of FIG. 12, a third redistribution structure 270 may be formed on a metal layer 280. First, a second dielectric layer 271 may be formed on the metal layer 280. In embodiments, the second dielectric layer 271 may be deposited by performing a spin coating process. In embodiments, the second dielectric layer 271 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. After this, an align key pattern AK may be formed within the second dielectric layer 271. In embodiments, the align key pattern AK may be formed by performing a photoresist process and an etching process on the second dielectric layer 271 to form openings, and performing an electrolytic plating process using the metal layer 280 as a seed metal layer. In embodiments, the align key pattern AK may include copper or a copper alloy. The vias 281 of the align key pattern AK may each have a shape in which the width in the horizontal direction increases from the bottom to the top. In the semiconductor package 200A that is the final product, the vias 281 of the alignment key pattern AK may have a shape in which the width in the horizontal direction decreases from the bottom to the top.

Referring to step (C) of FIG. 12, the second semiconductor dies SD2 may be aligned at the location where the second semiconductor die SD2 is to be disposed based on the alignment key pattern AK. After this, a second semiconductor die SD2 may be attached on the second dielectric layer 271 using an adhesive member AM. In embodiments, the adhesive member AM may include a die attach film DAF.

Referring to step (D) of FIG. 12, the second semiconductor die SD2 and the adhesive member AM may be molded with the second molding material 262 on the third redistribution structure 270. In embodiments, the process of molding with the second molding material 262 may include a compression molding or transfer molding process. In embodiments, the second molding material 262 may include an epoxy molding compound EMC.

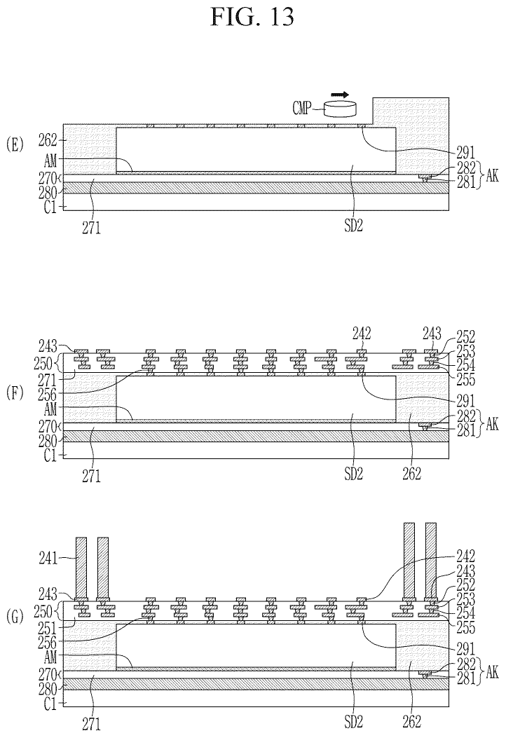

Referring to step (E) of FIG. 13, a chemical mechanical polishing CMP process may be performed. After performing the chemical mechanical polishing CMP process, the connection terminals 291 of the second semiconductor die SD2 may be exposed.

Referring to step (F) of FIG. 13, a second redistribution structure 250 may be formed on a second molding material 262. After forming a dielectric 251 on a second molding material 262, the dielectric 251 is selectively etched to form openings, and the openings are filled with a conductive material, thereby forming third redistribution vias 256, second redistribution lines 255, second redistribution vias 254, first redistribution lines 253, first redistribution vias 252, first bonding pads 242, and second bonding pads 243 sequentially from the bottom.

In embodiments, the dielectric 251 may be deposited by performing a spin coating process. In embodiments, the dielectric 251 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, a photoresist process and an etching process may be performed to etch the dielectric 251 and form openings in the dielectric 251. In embodiments, the third redistribution vias 256, the second redistribution lines 255, the second redistribution vias 254, the first redistribution lines 253, the first redistribution vias 252, the first bonding pads 242, and the second bonding pads 243 may each be formed by performing an electrolytic plating process after forming a seed metal layer. In embodiments, the third redistribution vias 256, the second redistribution lines 255, the second redistribution vias 254, the first redistribution lines 253, the first redistribution vias 252, the first bonding pads 242, and the second bonding pads 243 may each include at least one of copper, aluminum, tungsten, nickel, gold, tin, titanium, and alloys thereof.

Since the first redistribution vias 252, the second redistribution vias 254, and the third redistribution vias 256 are formed later by the chip first process, the first redistribution vias 252, the second redistribution vias 254, and the third redistribution vias 256 may each have a shape in which the width in the horizontal direction increases from the bottom to the top. In the semiconductor package (200A) that is the final product, the first redistribution vias 252, the second redistribution vias 254, and the third redistribution vias 256 may each have a shape in which the width in the horizontal direction decreases from the bottom to the top.

Referring to step (G) of FIG. 13, conductive posts 241 may be formed on the second bonding pads 243. Each of the conductive posts 241 may be formed to be disposed on a corresponding second bonding pad 243 among the second bonding pads 243. The conductive posts 241 may be formed by additionally depositing a photoresist on the second redistribution structure 250, selectively exposing and developing the photoresist to form a photoresist pattern including openings, and filling the openings with a conductive material. In embodiments, the conductive posts 241 may be formed by performing an electrolytic plating process after forming a seed metal layer. In embodiments, the conductive posts 241 may comprise copper or a copper alloy.

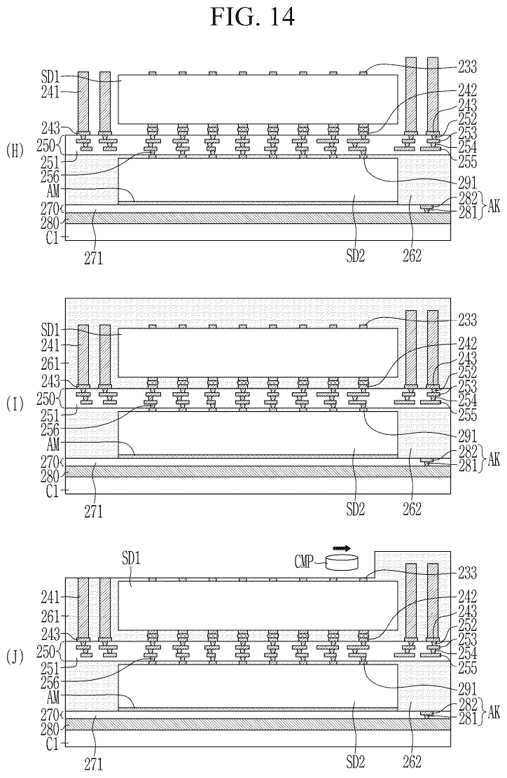

Referring to step (H) of FIG. 14, a first semiconductor die SD1 may be mounted on the first bonding pads 242. The first semiconductor die SD1 may be mounted on the first bonding pads 242 by flip chip bonding.

Referring to step (I) of FIG. 14, on the second redistribution structure 250, the first semiconductor die SD1, the bump structures 230, and the conductive posts 241 may be molded with the first molding material 261. In embodiments, the process of molding with the first molding material 261 may include a compression molding or transfer molding process. In embodiments, the first molding material 261 may include an epoxy molding compound EMC.

Referring to step (J) of FIG. 14, a chemical mechanical polishing CMP process may be performed. After performing the chemical mechanical polishing CMP process, the ends of the connection terminals 233 and the ends of the conductive posts 241 may be exposed.

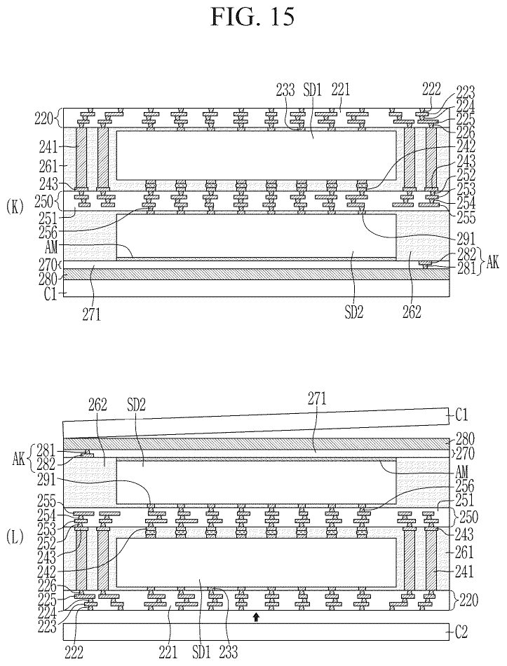

Referring to step (K) of FIG. 15, a first redistribution structure 220 may be formed on the conductive posts 241, the connecting terminals 233, and the first molding material 261. After a dielectric 221 is deposited on the conductive posts 241, the connection terminals 233, and the first molding material 261, the dielectric 221 is selectively etched to form openings, and the openings are filled with a conductive material, thereby forming third redistribution vias 226, second redistribution lines 225, second redistribution vias 224, first redistribution lines 223, and first redistribution vias 222 sequentially from the bottom.

In embodiments, the dielectric 221 may be deposited by performing a spin coating process. In embodiments, the dielectric 221 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, a photoresist process and an etching process may be performed to etch the dielectric 221 and form openings in the dielectric 221. In embodiments, the first redistribution vias 222, the first redistribution lines 223, the second redistribution vias 224, the second redistribution lines 225, and the third redistribution vias 226 may each be formed by performing an electrolytic plating process after forming a seed metal layer. In embodiments, the first redistribution vias 222, the first redistribution lines 223, the second redistribution vias 224, the second redistribution lines 225, and the third redistribution vias 226 may each include at least one of copper, aluminum, tungsten, nickel, gold, tin, titanium, and alloys thereof.

Since the first redistribution vias 222, the second redistribution vias 224, and the third redistribution vias 226 are formed later by the chip first process, the first redistribution vias 222, the second redistribution vias 224, and the third redistribution vias 226 may each have a shape in which the width in the horizontal direction increases from the bottom to the top. In the semiconductor package 200A that is the final product, the first redistribution vias 222, the second redistribution vias 224, and the third redistribution vias 226 may each have a shape in which the width in the horizontal direction decreases from the bottom to the top.

Referring to step (L) of FIG. 15, the first carrier C1 may be removed and a second carrier C2 may be attached to the first redistribution structure 220.

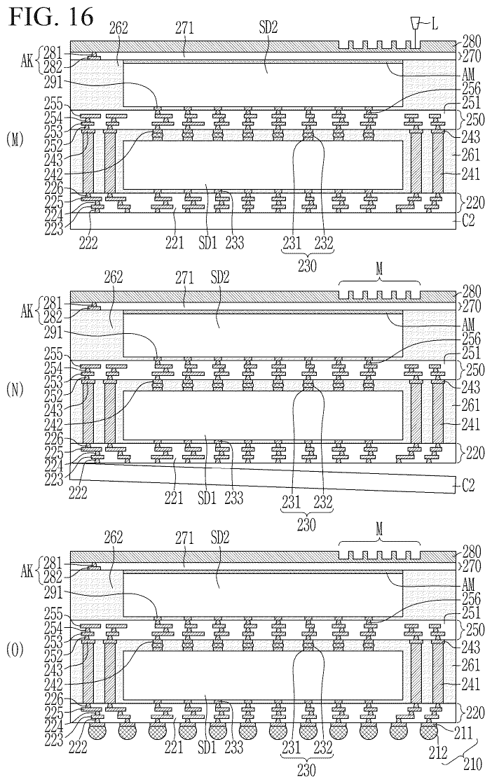

Referring to step (M) of FIG. 16, recesses may be formed according to a marking pattern M to be formed using a laser L. Since the marking pattern M is formed on a metal layer 280 having a relatively higher light reflectance than the light reflectance of the dielectric layer for marking, the semiconductor package 200A may have a marking pattern M with improved visibility.

Referring to step (N) of FIG. 16, the second carrier C2 may be removed.

Referring to step (O) of FIG. 16, an external connection structure 210 may be formed on the first redistribution structure 220. Conductive pads 211 may be formed on the first redistribution vias 222 of the first redistribution structure 220. In embodiments, the conductive pads 211 may include at least one of copper, nickel, zinc, gold, silver, platinum, palladium, chromium, titanium, and alloys thereof. In embodiments, the conductive pads 211 may be formed by performing a sputtering process or by performing an electrolytic plating process after forming a seed metal layer. After this, an external connecting member 212 may be formed on each of the conductive pads 211. In embodiments, the external connecting members 212 may include at least one of tin, silver, lead, nickel, copper, and alloys thereof.

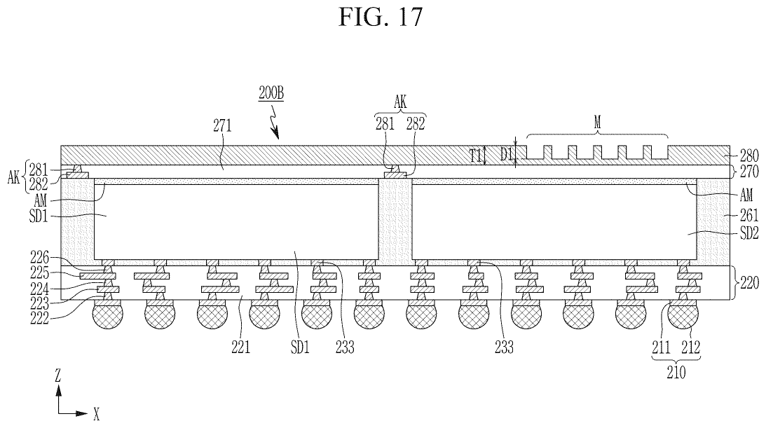

FIG. 17 is a cross-sectional view illustrating a semiconductor package (200B) of embodiments.

Referring to FIG. 17, a semiconductor package 200B may include an external connection structure 210, a front side redistribution structure 220, a first semiconductor die SD1, a second semiconductor die SD2, an adhesive member AM, a molding material 261, a back side redistribution structure 270, and a metal layer 280. In embodiments, the semiconductor package 200B may include a Side by Side package. In embodiments, the semiconductor package 200B may be a semiconductor package manufactured based on fan-out wafer level package FOWLP or fan-out panel level package FOPLP technology. In embodiments according to the present disclosure, a semiconductor package 200B including a first semiconductor die SD1 and a second semiconductor die SD2 is illustrated and described, but is not limited thereto, and a semiconductor package 200B including more semiconductor dies SD may be included in the present disclosure.

The first semiconductor die SD1 and the second semiconductor die SD2 may be disposed on the front side redistribution structure 220. The first semiconductor die SD1 may be disposed next to the second semiconductor die SD2. The first semiconductor die SD1 may be disposed side by side with the second semiconductor die SD2. The first semiconductor die SD1 and the second semiconductor die SD2 may be electrically connected to the front side redistribution structure 220 by connection terminals 233. In embodiments, the first semiconductor die SD1 may include a logic die. In embodiments, the first semiconductor die SD1 may include a System on Chip SoC. In embodiments, the first semiconductor die SD1 may include an Application Processor AP. In embodiments, the first semiconductor die SD1) may include at least one of a Central Processing Unit CPU, a Graphic Processing Unit GPU, a signal processor, a network processor, and a codec. In embodiments, the second semiconductor die SD2 may include a single chip, such as a DRAM, or multiple chips, such as a high bandwidth memory HBM.

The adhesive member AM may attach the first semiconductor die SD1 and the second semiconductor die SD2 to the back side redistribution structure 270. In embodiments, the adhesive member AM may include a die attach film DAF.

The molding material 261 may cover the first semiconductor die SD1, the second semiconductor die SD2, and the adhesive members AM on the front side redistribution structure 220. The molding material 261 protects the first semiconductor die SD1, the second semiconductor die SD2, and the adhesive members AM from the external environment, thereby ensuring the electrical and mechanical stability of the semiconductor package 200B.

The back side redistribution structure 270 may be disposed on the adhesive member AM and the molding material 261. The back side redistribution structure 270 may include a dielectric layer 271 and an alignment key pattern AK within the dielectric layer 271. The align key pattern AK may include vias 281 and an align key 282. The align key pattern AK may include an align key 282 and may not include vias 281. In other embodiments, a back side redistribution structure 270 including fewer or more align key patterns AK may be included within the scope of the present disclosure.

The dielectric layer 271 may protect and insulate the alignment key pattern AK. An adhesive member AM and a molding material 261 may be disposed on the first surface of the dielectric layer 271. The first surface of the dielectric layer 171 may contact the molding material 261. A metal layer 280 may be disposed on the second surface of the dielectric layer 271. The second surface may be the opposite surface of the first surface. All of the second surface of the dielectric layer 271 may be covered by the metal layer 280.

The align key pattern AK may be exposed from the first surface of the dielectric layer 271. The align key pattern AK may penetrate the dielectric layer 271. The align key pattern AK may extend from the metal layer 280. The alignment key 282 serves as a reference for the arrangement direction of the first semiconductor die SD1 and the second semiconductor die SD2 during the process of attaching the first semiconductor die SD1 and the second semiconductor die SD2 to the back side redistribution structure 270, thereby preventing the first semiconductor die SD1 and the second semiconductor die SD2 from being misaligned. Vias 281 may be disposed between the metal layer 280 and the align key 282. The vias 281 may extend in the vertical direction within the dielectric layer 271. The vias 282 may each have a shape in which the width in the horizontal direction decreases from the bottom to the top.

A metal layer 280 may be disposed on the back side redistribution structure 270. The metal layer 280 may cover all of the upper surface of the back side redistribution structure 270. The metal layer 280 may cover the entire second surface of the dielectric layer 271. The metal layer 280 may include a third surface contacting the dielectric layer 271 and a fourth surface opposite the third surface. The metal layer 280 may include a marking pattern M. The marking pattern M is a mark engraved on the metal layer 280 using a laser. The marking pattern M may function as an alignment mark or a recognition mark. The alignment mark may include various geometric shapes, such as a cross, a square, or a circle. The recognition mark may include, for example, product information such as letters or numbers, a barcode, a QR code, a manufacturer's name, a product model name, or a brand name. The marking pattern M may be a pattern recessed from the fourth surface. The metal layer 280 may have a first thickness T1 in the vertical direction (Z direction). In embodiments, the first thickness T1 may have a range of about 10 μm to about 40 μm. The marking pattern M may have a cross-sectional shape that is recessed in the vertical direction (Z direction) by a first depth D1 from the fourth surface of the metal layer 280. In embodiments, the first depth D1 may have a range of about 8 μm to about 38 μm. The first depth D1 may be less than the first thickness T1.

For contents other than those described for the semiconductor package 200B of embodiments in FIG. 17, the contents described for the semiconductor package 200A in FIG. 11 may be applied.

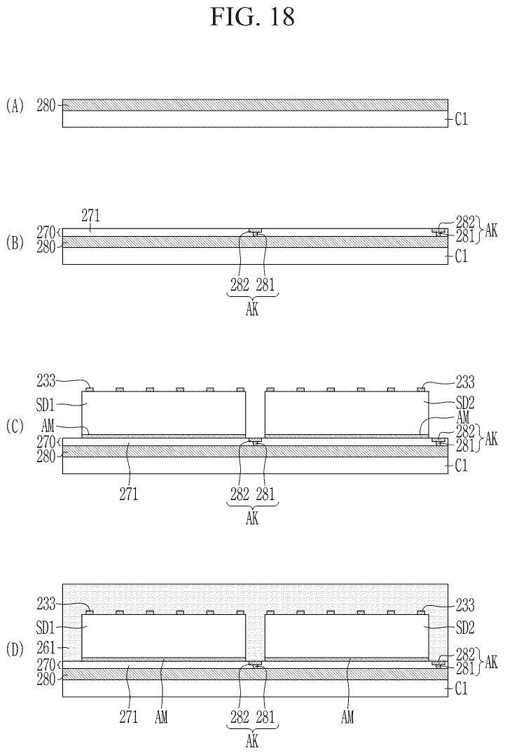

FIGS. 18 to 20 are cross-sectional views illustrating a method for manufacturing a semiconductor package 200B of FIG. 17.

Referring to step (A) of FIG. 18, a first carrier C1 may be provided. In embodiments, the first carrier C1 may include a silicon-based material, such as glass or silicon oxide, another material such as an organic material or aluminum oxide, or any combination of these materials. A metal layer 280 may be deposited on the first carrier C1. The metal layer 280 may be a seed metal layer. In embodiments, the metal layer 280 may be formed by performing a sputtering process or an electroless plating process. In embodiments, the metal layer 280 may include copper or a copper alloy. The metal layer 280 may be formed thicker than a typical seed metal layer to form a marking pattern M in a subsequent process. The metal layer 280 may have both the function of a seed metal layer and the function of an object on which a marking pattern M is engraved. According to the present disclosure, a seed metal layer, which is essentially deposited to form a redistribution via and a redistribution line of a redistribution structure, may be formed thickly, and a marking pattern may be formed on the thickly formed seed metal layer in a subsequent process. Accordingly, the process performed to form a dielectric layer for marking may be omitted in the manufacturing process of the semiconductor package 200B.

Referring to step (B) of FIG. 18, a back side redistribution structure 270 may be formed on a metal layer 280. First, a dielectric layer 271 may be formed on a metal layer 280. In embodiments, the dielectric layer 271 may be deposited by performing a spin coating process. In embodiments, the dielectric layer 271 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. After this, an alignment key pattern AK may be formed within the dielectric layer 271. In embodiments, the align key pattern AK may be formed by performing a photoresist process and an etching process on the dielectric layer 271 to form openings, and performing an electrolytic plating process using the metal layer 280 as a seed metal layer. In embodiments, the align key pattern AK may include copper or a copper alloy. The vias 281 of the align key pattern AK may each have a shape in which the width in the horizontal direction increases from the bottom to the top. In the semiconductor package 200B that is the final product, the vias 281 of the alignment key pattern AK may have a shape in which the width in the horizontal direction decreases from the bottom to the top.

Referring to step (C) of FIG. 18, based on the align key pattern AK, the first semiconductor die SD1 may be aligned at a position where the first semiconductor die SD1 is to be disposed, and the second semiconductor die SD2 may be aligned at a position where the second semiconductor die SD2 is to be disposed. After this, the first semiconductor die SD1 and the second semiconductor die SD2 may be attached on the dielectric layer 271 using adhesive members AM. In embodiments, the adhesive member AM may include a die attach film DAF.

Referring to step (D) of FIG. 18, the first semiconductor die SD1, the second semiconductor die SD2, and the adhesive members AM may be molded with a molding material 261 on the back side redistribution structure 270. In embodiments, the process of molding with the molding material 261 may include a compression molding or transfer molding process. In embodiments, the molding material 261 may include an epoxy molding compound EMC.

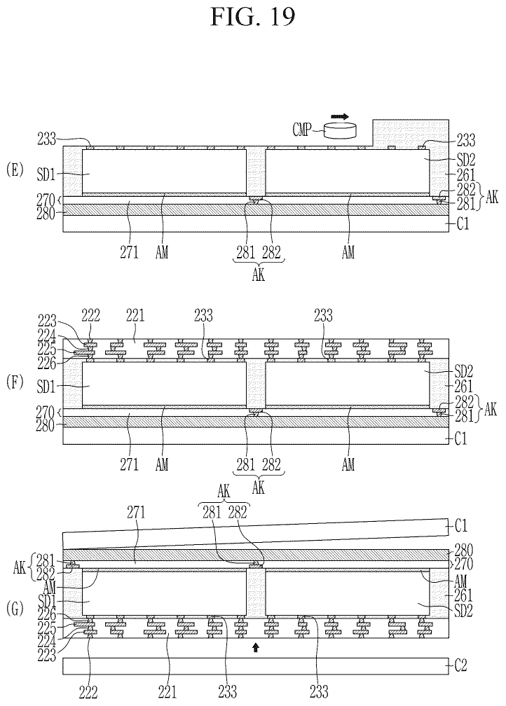

Referring to step (E) of FIG. 19, a chemical mechanical polishing CMP process may be performed. After performing the chemical mechanical polishing CMP process, the connection terminals 233 of the first semiconductor die SD1 and the connection terminals 233 of the second semiconductor die SD2 may be exposed.

Referring to step (F) of FIG. 19, a front side redistribution structure 220 may be formed on the connection terminals 233 and the first molding material 261. After forming a dielectric 221 on the connection terminals 233 and the first molding material 261, the dielectric 221 is selectively etched to form openings, and the openings are filled with a conductive material, thereby forming third redistribution vias 226, second redistribution lines 225, second redistribution vias 224, first redistribution lines 223, and first redistribution vias 222 sequentially from the bottom.

In embodiments, the dielectric 221 may be deposited by performing a spin coating process. In embodiments, the dielectric 221 may include a photo imageable dielectric PID used in the redistribution process. In embodiments, the photo imageable dielectric PID may include a polyimide-based photo imageable polymer, a novolak-based photo imageable polymer, a polybenzoxazole, a silicone-based polymer, an acrylate-based polymer, or an epoxy-based polymer. In embodiments, a photoresist process and an etching process may be performed to etch the dielectric 121 and form openings in the dielectric 121. In embodiments, the first redistribution vias 222, the first redistribution lines 223, the second redistribution vias 224, the second redistribution lines 225, and the third redistribution vias 226 may each be formed by performing an electrolytic plating process after forming a seed metal layer. In embodiments, the first redistribution vias 222, the first redistribution lines 223, the second redistribution vias 224, the second redistribution lines 225, and the third redistribution vias 226 may each include at least one of copper, aluminum, tungsten, nickel, gold, tin, titanium, and alloys thereof.

Since the first redistribution vias 222, the second redistribution vias 224, and the third redistribution vias 226 are formed later by the chip first process, the first redistribution vias 222, the second redistribution vias 224, and the third redistribution vias 226 may each have a shape in which the width in the horizontal direction increases from the bottom to the top. In the semiconductor package 200B that is the final product, the first redistribution vias 222, the second redistribution vias 224, and the third redistribution vias 226 may each have a shape in which the width in the horizontal direction decreases from the bottom to the top.

Referring to step (G) of FIG. 19, the first carrier C1 may be removed and a second carrier C2 may be attached to the front side redistribution structure 220.

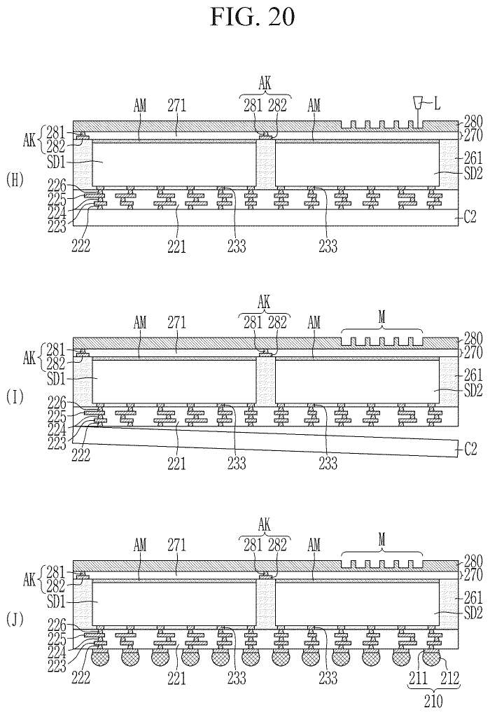

Referring to step (H) of FIG. 20, recesses may be formed according to a marking pattern M to be formed using a laser L. Since the marking pattern M is formed on a metal layer 280 having a relatively higher light reflectance than the light reflectance of the dielectric layer for marking, the semiconductor package 200B may have a marking pattern M with improved visibility.

Referring to step (I) of FIG. 20, the second carrier C2 may be removed.

Referring to step (J) of FIG. 20, an external connection structure 210 may be formed on a front side redistribution structure 220. Conductive pads 211 may be formed on the first redistribution vias 222 of the front side redistribution structure 220. In embodiments, the conductive pads 211 may include at least one of copper, nickel, zinc, gold, silver, platinum, palladium, chromium, titanium, and alloys thereof. In embodiments, the conductive pads 211 may be formed by performing a sputtering process or by performing an electrolytic plating process after forming a seed metal layer. After this, an external connecting member 212 may be formed on each of the conductive pads 211. In embodiments, the external connecting members 212 may include at least one of tin, silver, lead, nickel, copper, and alloys thereof.

Although the preferred embodiments of the present disclosure have been described above, the present disclosure is not limited thereto, and various modifications may be made within the scope of the claims, the detailed description of the invention, and the attached drawings, which should also fall within the scope of the present disclosure.

What is claimed is:

1. A semiconductor package comprising:
a redistribution structure;
a semiconductor die on the redistribution structure;
a molding material covering the semiconductor die on the redistribution structure;
a dielectric layer on the molding material, the dielectric layer including a first surface contacting the molding material and a second surface opposite the first surface; and
a metal layer covering all of the second surface and including a marking pattern.

2. The semiconductor package of claim 1, further comprising:
an align key pattern exposed from the first surface of the dielectric layer.

3. The semiconductor package of claim 2, wherein:
the alignment key pattern penetrates the dielectric layer.

4. The semiconductor package of claim 2, wherein:
the alignment key pattern extends from the metal layer.

5. The semiconductor package of claim 1, wherein:
the metal layer comprises a third surface contacting the dielectric layer and a fourth surface opposite the third surface, and
the marking pattern has a cross-sectional shape that is recessed in a vertical direction from the fourth surface by a first depth.

6. The semiconductor package of claim 5, wherein:
the metal layer has a first thickness in the vertical direction, and
the first depth is less than the first thickness.

7. The semiconductor package of claim 6, wherein:
the first thickness has a range of about 10 μm to about 40 μm.

8. The semiconductor package of claim 6, wherein:
the first depth has a range of about 8 μm to about 38 μm.

9. The semiconductor package of claim 1, wherein:
the dielectric layer comprises a photo imageable dielectric (PID).

10. The semiconductor package of claim 1, wherein:
the metal layer comprises copper or a copper alloy.

11. The semiconductor package of claim 2, wherein:
the alignment key pattern comprises copper or a copper alloy.

12. A semiconductor package comprising:
a redistribution structure;
a plurality of conductive posts on the redistribution structure;
a semiconductor stack on the redistribution structure, the semiconductor stack comprising a plurality of semiconductor dies that are stacked, the semiconductor stack being disposed to be spaced apart in a vertical direction from the redistribution structure, and each of the plurality of conductive posts being connected to a corresponding semiconductor die among the plurality of semiconductor dies;
a molding material covering the semiconductor stack and the plurality of conductive posts on the redistribution structure;
a dielectric layer on the molding material, the dielectric layer comprising a first surface contacting the semiconductor stack and the molding material, and a second surface opposite the first surface; and
a metal layer covering all of the second surface and comprising a marking pattern.

13. The semiconductor package of claim 12, wherein:
the plurality of semiconductor dies are stacked sequentially from below and with an offset in a first horizontal direction.

14. The semiconductor package of claim 12, wherein:
the semiconductor stack further comprises a plurality of adhesive members, and
the plurality of adhesive members are disposed alternately with the plurality of semiconductor dies.

15. The semiconductor package of claim 12, wherein:
each of the plurality of semiconductor dies comprises an active surface facing the redistribution structure,
each of the plurality of semiconductor dies comprises a plurality of connection pads on the active surface, and
each of the plurality of conductive posts is connected to a corresponding connection pad among the plurality of connection pads.

16. A semiconductor package comprising:
a first redistribution structure;
a plurality of first conductive posts on the first redistribution structure;
a plurality of second conductive posts on the first redistribution structure;
a first semiconductor stack on the first redistribution structure, the first semiconductor stack comprising a plurality of first semiconductor dies that are stacked, the first semiconductor stack being disposed to be vertically spaced apart from the first redistribution structure, each of the plurality of first conductive posts being connected to a corresponding first semiconductor die of the plurality of first semiconductor dies;
a first molding material covering the first semiconductor stack, the plurality of first conductive posts, and the plurality of second conductive posts on the first redistribution structure;
a second redistribution structure on the first molding material, the second redistribution structure comprising a first dielectric layer and a plurality of vias in the first dielectric layer, each of the plurality of second conductive posts being connected to a corresponding via of the plurality of vias;
a plurality of third conductive posts on the second redistribution structure;
a second semiconductor stack on the second redistribution structure, the second semiconductor stack comprising a plurality of second semiconductor dies that are stacked, the second semiconductor stack being disposed to be vertically spaced apart from the second redistribution structure, each of the plurality of third conductive posts being connected to a corresponding second semiconductor die of the plurality of second semiconductor dies;
a second molding material covering the second semiconductor stack and the plurality of third conductive posts on the second redistribution structure;
a second dielectric layer on the second molding material, the second dielectric layer comprising a first surface contacting the second semiconductor stack and the second molding material, and a second surface opposite the first surface; and
a metal layer covering all of the second surface and comprising a marking pattern.

17. The semiconductor package of claim 16, wherein:
the first molding material covers between the first redistribution structure and the first semiconductor stack, and side surfaces of the first semiconductor stack.

18. The semiconductor package of claim 16, wherein:
the second molding material covers between the second redistribution structure and the second semiconductor stack, and side surfaces of the second semiconductor stack.

19. The semiconductor package of claim 16, wherein:
the second redistribution structure is in contact with the first semiconductor stack.

20. The semiconductor package of claim 16, wherein:
the plurality of vias penetrate the first dielectric layer.
